(19) United States
(12) Patent Application Publication
(10) Pub. No.: US 2013/0108804 A1
(43) Pub. Date: May 2, 2013

(54) PLASMA TREATMENT OF SUBSTRATES

(71) Applicants: Francoise Massines, Sorede (FR); Adrien Toutant, Villeneuve De La Raho (FR); Thomas Gaudy, Montescot (FR); Pierre Descamps, Rixensart (BE); Patrick Leempoel, Bruxelles (BE); Vincent Kaiser, Seneffe (BE)

(72) Inventors: Francoise Massines, Sorede (FR); Adrien Toutant, Villeneuve De La Raho (FR); Thomas Gaudy, Montescot (FR); Pierre Descamps, Rixensart (BE); Patrick Leempoel, Bruxelles (BE); Vincent Kaiser, Seneffe (BE)

(21) Appl. No.: 13/700,838

(22) PCT Filed: Jul. 20, 2011
(86) PCT No.: PCT/EP2011/003624

§ 371 Date: Jan. 11, 2013

(30) Foreign Application Priority Data
Jul. 21, 2010 (EP) 10305808
Jan. 20, 2011 (EP) 11305059.5
Apr. 27, 2011 (EP) 11305494.4

(51) Int. Cl. B05D 1/00; C23C 16/509

(52) U.S. Cl. CPC B05D 1/62; C23C 16/509
USPC 427/569; 118/723 E

(57) ABSTRACT

A process for plasma treating a substrate comprises applying a radio frequency high voltage to at least one electrode positioned within a dielectric housing having an inlet and an outlet while causing a process gas to flow from the inlet past the electrode to the outlet, thereby generating a non-equilibrium atmospheric pressure plasma. An atomized or gaseous surface treatment agent is incorporated in the non-equilibrium atmospheric pressure plasma. The substrate is positioned adjacent to the plasma outlet so that the surface is in contact with the plasma and is moved relative to the plasma outlet. The flow of process gas and the gap between the plasma outlet and the substrate are controlled so that the process gas has a turbulent flow regime within the dielectric housing.

The present invention relates to treating a substrate using a plasma system. In particular it relates to the deposition of a thin film on a substrate from a non-equilibrium atmospheric pressure plasma incorporating an atomized surface treatment agent.

When matter is continually supplied with energy, its temperature increases and it typically transforms from a solid to a liquid and, then, to a gaseous state. Continuing to supply energy causes the system to undergo yet a further change of state in which neutral atoms or molecules of the gas are broken up by energetic collisions to produce negatively charged electrons, positive or negatively charged ions and other excited species. This mix of charged and other excited particles exhibiting collective behaviour is called “plasma”, the fourth state of matter. Due to their electrical charge, plasmas are highly influenced by external electromagnetic fields, which make them readily controllable. Furthermore, their high energy content allows them to achieve processes which are impossible or difficult through the other states of matter, such as by liquid or gas processing.

The term “plasma” covers a wide range of systems whose density and temperature vary by many orders of magnitude. Some plasmas are very hot and all their microscopic species (ions, electrons, etc.) are in approximate thermal equilibrium, the energy input into the system being widely distributed through atomic/molecular level collisions. Other plasmas, however, have their constituent species at widely different temperatures and are called “non-thermal equilibrium” plasmas. In these non-thermal plasmas the free electrons are very hot with temperatures of many thousands of Kelvin (K) whilst the neutral and ionic species remain cool. Because the free electrons have almost negligible mass, the total system heat content is low and the plasma operates close to room temperature thus allowing the processing of temperature sensitive materials, such as plastics or polymers, without imposing a damaging thermal burden onto the sample. However, the hot electrons create, through high energy collisions, a rich source of radicals and excited species with a high chemical potential energy capable of profound chemical and physical reactivity. It is this combination of low temperature operation plus high reactivity which makes non-thermal plasma technologically important and a very powerful tool for manufacturing and material processing, capable of achieving processes which, if achievable at all without plasma, would require very high temperatures or noxious and aggressive chemicals.

For industrial applications of plasma technology, a convenient method is to couple electromagnetic power into a volume of process gas. A process gas may be a single gas or a mixture of gases and vapours which is excitable to a plasma state by the application of the electromagnetic power. Workpieces/samples are treated by the plasma generated by being immersed or passed through the plasma itself or charged and/or excited species derived therefrom because the process gas becomes ionised and excited, generating species including chemical radicals, and ions as well as UV-radiation, which can react or interact with the surface of the workpieces/samples. By correct selection of process gas composition, driving power frequency, power coupling mode, pressure and other control parameters, the plasma process can be tailored to the specific application required by a manufacturer.

Because of the huge chemical and thermal range of plasmas, they are suitable for many technological applications. Non-thermal equilibrium plasmas are particularly effective for surface activation, surface cleaning, material etching and coating of surfaces.

Since the 1960s the microelectronics industry has developed the low pressure Glow Discharge plasma into an ultra-high technology and high capital cost engineering tool for semiconductor, metal and dielectric processing. The same low pressure Glow Discharge type plasma has increasingly penetrated other industrial sectors since the 1980s offering polymer surface activation for increased adhesion/bond strength, high quality degreasing/cleaning and the deposition of high performance coatings. Glow discharges can be achieved at both vacuum and atmospheric pressures. In the case of atmospheric pressure glow discharge, gases such as helium, argon or nitrogen are utilised as diluents and a high frequency (e.g. >1 kHz) power supply is used to generate a homogeneous glow discharge at atmospheric pressure, with Penning ionisation mechanism being possibly dominant in He/N2 mixtures with respect to primary ionisation by electrons, (see for example, Kanazawa et al, J. Phys. D: Appl. Phys. 1988, 21, 838, Okazaki et al, Proc. Jpn. Symp. Plasma Chem. 1989, 2, 95, Kanazawa et al, Nuclear Instruments and Methods in Physical Research 1989, B37/38, 842, and Yokoyama et al., J. Phys. D: Appl. Phys. 1990, 23, 374).

A variety of “plasma jet” systems have been developed, as means of atmospheric pressure plasma treatment. Plasma jet systems generally consist of a gas stream which is directed between two electrodes. As power is applied between the electrodes, a plasma is formed and this produces a mixture of ions, radicals and active species which can be used to treat various substrates. The plasma produced by a plasma jet system is directed from the space between the electrodes (the plasma zone) as a flame-like phenomenon and can be used to treat remote objects.

U.S. Pat. Nos. 5,198,724 and 5,369,336 describe “cold” or non-thermal equilibrium atmospheric pressure plasma jet (hereafter referred to as APPJ), which consisted of an RF powered metal needle acting as a cathode, surrounded by an outer cylindrical anode. U.S. Pat. No. 6,429,400 describes a system for generating a blown atmospheric pressure glow discharge (APGD). This comprises a central electrode separated from an outer electrode by an electrical insulator tube. The inventor claims that the design does not generate the high temperatures associated with the prior art. Kang et al (Surf Coat. Technol., 2002, 171, 141-148) have also described a 13.56 MHz RF plasma source that operates by feeding helium or argon gas through two coaxial electrodes. In order to prevent an arc discharge, a dielectric material is loaded outside the central electrode. WO94/14303 describes a device in which an electrode cylinder has a pointed portion at the exit to enhance plasma jet formation.

U.S. Pat. No. 5,837,958 describes an APPJ based on coaxial metal electrodes where a powered central electrode and a dielectric coated ground electrode are utilised. A portion of the ground electrode is left exposed to form a bare ring electrode near the gas exit. The gas flow (air or argon) enters through the top and is directed to form a vortex, which keeps the arc confined and focused to form a plasma jet. To cover a wide area, a number of jets can be combined to increase the coverage.

U.S. Pat. No. 6,465,964 describes an alternative system for generating an APPJ, in which a pair of electrodes is placed around a cylindrical tube. Process gas enters through the top of the tube and exits through the bottom. When an AC electric field is supplied between the two electrodes, a plasma is generated by passing a process gas therebetween within the tube and this gives rise to an APPJ at the exit. The position of the electrodes ensures that the electric field forms in the axial direction. In order to extend this technology to the coverage of wide area substrates, the design can be modified, such that the central tube and electrodes are redesigned to have a rectangular tubular shape. This gives rise to a wide area plasma, which can be used to treat large substrates such as reel-to-reel plastic film.

U.S. Pat. No. 5,798,146 describes formation of plasma using a single sharp needle electrode placed inside a tube and applying a high voltage to the electrode produces a leakage of electrons, which further react with the gas surrounding the electrode, to produce a flow or ions and radicals. As there is no second electrode, this does not result in the formation of an arc. Instead, a low temperature plasma is formed which is carried out of the discharge space by a flow of gas. Various nozzle heads have been developed to focus or spread the plasma. The system may be used to activate, clean or etch various substrates. Stoffels et al (Plasma Sources Sci. Technol., 2002, 11, 383-388) have developed a similar system for biomedical uses.

WO 02/028548 describes a method for forming a coating on a substrate by introducing an atomized liquid and/or solid coating material into an atmospheric pressure plasma discharge or an ionized gas stream resulting therefrom. WO 02/098962 describes coating a low surface energy substrate by exposing the substrate to a silicon compound in liquid or gaseous form and subsequently post-treating by oxidation or reduction using a plasma or corona treatment, in particular a pulsed atmospheric pressure glow discharge or dielectric barrier discharge.

WO 03/097245 and WO 03/101621 describe applying an atomized coating material onto a substrate to form a coating. The atomized coating material, upon leaving an atomizer such as an ultrasonic nozzle or a nebuliser, passes through an excited medium (plasma) to the substrate. The substrate is positioned remotely from the excited medium. The plasma is generated in a pulsed manner.

WO2006/048649 describes generating a non-equilibrium atmospheric pressure plasma incorporating an atomized surface treatment agent by applying a radio frequency high voltage to at least one electrode positioned within a dielectric housing having an inlet and an outlet while causing a process gas to flow from the inlet past the electrode to the outlet. The electrode is combined with an atomizer for the surface treatment agent within the housing. The non-equilibrium atmospheric pressure plasma extends from the electrode at least to the outlet of the housing so that a substrate placed adjacent to the outlet is in contact with the plasma, and usually extends beyond the outlet. WO2006/048650 teaches that the flame-like non-equilibrium plasma discharge, sometimes called a plasma jet, could be stabilized over considerable distances by confining it to a long length of tubing. This prevents air mixing and minimises quenching of the flame-like non-equilibrium plasma discharge. The flame-like non-equilibrium plasma discharge extends at least to the outlet, and usually beyond the outlet, of the tubing.

WO03/085693 describes an atmospheric plasma generation assembly having a reactive agent introducing means, a process gas introducing means and one or more multiple parallel electrode arrangements adapted for generating a plasma. The assembly is adapted so that the only means of exit for a process gas and atomized liquid or solid reactive agent introduced into said assembly is through the plasma region between the electrodes. The assembly is adapted to move relative to a substrate substantially adjacent to the electrodes outermost tips. Turbulence may be generated in the plasma generation assembly to ensure an even distribution of the atomized spray, for example by introducing process gas perpendicular to the axis of the body such that turbulence is generated close to the ultrasonic spray nozzle outlet as the gas flow reorientates to the main direction of flow along the length of the axis. Alternatively turbulence can be induced by positioning a restrictive flow disc in the process gas flow field just upstream of the ultrasonic spray nozzle tip.

The paper “Generation of long laminar plasma jets at atmospheric pressure and effects of flow turbulence” by Wenxia Pan et al in ‘Plasma Chemistry and Plasma Processing’, Vol. 21, No. 1, 2001 shows that laminar flow plasma with very low initial turbulent kinetic energy will produce a long jet with low axial temperature gradient and suggests that this kind of long laminar plasma jet could greatly improve the controllability for materials processing, compared with a short turbulent arc jet.

The paper “Analysis of mass transport in an atmospheric pressure remote plasma enhanced chemical vapor deposition process” by R. P. Cardoso et al in ‘Journal of Applied Physics’ Vol. 107, 024909 (2010) shows that in remote microwave plasma enhanced chemical vapor deposition processes operated at atmospheric pressure, high deposition rates are associated with the localization of precursors on the treated surface, and that mass transport can be advantageously ensured by convection for the heavier precursor, the lighter being driven by turbulent diffusion toward the surface.

The use of atmospheric plasma technologies for thin film deposition offers a lot of benefits versus alternative low pressure plasma deposition in terms of capital cost (no need for vacuum chamber or vacuum pumps) or maintenance. This is particularly true for a jet-like system that allows precise deposition on the substrate. The plasma jet technology of WO2006/048649 and WO2006/048650 has been used successfully to deposit many surface treatment agents as a thin film on a substrate. One problem which has been encountered when the surface treatment agent is a polymerisable precursor is the polymerization of precursor within the plasma zone leading to the deposition of powdery material and formation of a coating film of low density.

WO2009/034012 describes a process for coating a surface, in which an atomized surface treatment agent is incorporated in a non-equilibrium atmospheric pressure plasma generated in a noble process gas or an excited and/or ionised gas stream resulting therefrom, and the surface to be treated is positioned to receive atomized surface treatment agent which has been incorporated therein, is characterized in that the particle content of the coating formed on the surface is reduced by incorporating a minor proportion of nitrogen in the process gas. However the addition of nitrogen is detrimental to the energy available for precursor dissociation.

In a process according to the present invention for plasma treating a substrate by applying a radio frequency high voltage to at least one electrode positioned within a dielectric housing having an inlet and an outlet while causing a process gas to flow from the inlet past the electrode to the outlet, thereby generating a non-equilibrium atmospheric pressure plasma, incorporating an atomized surface treatment agent in the non-equilibrium atmospheric pressure plasma, and positioning the substrate adjacent to the outlet of the dielectric housing so that the surface of the substrate is in contact with the plasma and is moved relative to the outlet of the dielectric housing, the flow of process gas and the gap between the outlet of the dielectric housing and the substrate are controlled so that the process gas has a turbulent flow regime within the dielectric housing.

The dielectric housing (14) defines a ‘plasma tube’ (13) within which the non-equilibrium atmospheric pressure plasma is formed. We have found that by creating a turbulent gas flow regime within the plasma tube (13) a more uniform non-equilibrium atmospheric pressure plasma is achieved, leading to a better and more uniform deposition on the substrate of a film derived from the surface treatment agent.

In a preferred process according to the invention for promoting a turbulent flow regime within the dielectric housing, the surface area of the gap between the outlet of the dielectric housing and the substrate is less than 35 times the area of the inlet for process gas. If the dielectric housing has more than one inlet for process gas, the surface area of the gap between the outlet of the dielectric housing and the substrate is less than 35 times the sum of the areas of the inlets for process gas.

The invention includes an apparatus for plasma treating a substrate, comprising a radio frequency high voltage source connected to at least one electrode positioned within a dielectric housing having an inlet for process gas and an outlet arranged so that process gas flows from the inlet past the electrode to the outlet, means for introducing an atomized surface treatment agent in the dielectric housing, and support means for the substrate adjacent to the outlet of the dielectric housing, characterised in that the support means are positioned so that the surface area of the gap between the outlet of the dielectric housing and the substrate is less than 35 times the area of the inlet for process gas

The plasma can in general be any type of non-equilibrium atmospheric pressure plasma or corona discharge. Examples of non-equilibrium atmospheric pressure plasma discharge include dielectric barrier discharge and diffuse dielectric barrier discharge such as glow discharge plasma. A diffuse dielectric barrier discharge e.g. a glow discharge plasma is preferred. Preferred processes are “low temperature” plasmas wherein the term “low temperature” is intended to mean below 200° C., and preferably below 100° C. These are plasmas where collisions are relatively infrequent (when compared to thermal equilibrium plasmas such as flame based systems) which have their constituent species at widely different temperatures (hence the general name “non-thermal equilibrium” plasmas).

The invention will be described with reference to the accompanying drawings, of which

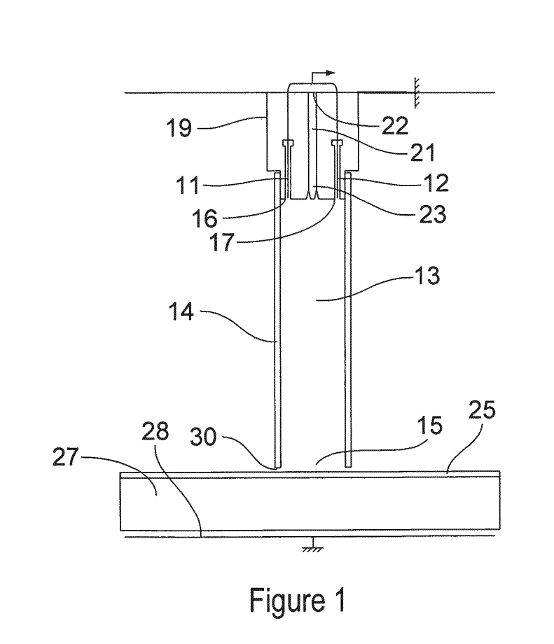

FIG. 1 is a diagrammatic cross section of an apparatus according to the invention for generating a non-equilibrium atmospheric pressure plasma incorporating an atomized surface treatment agent:

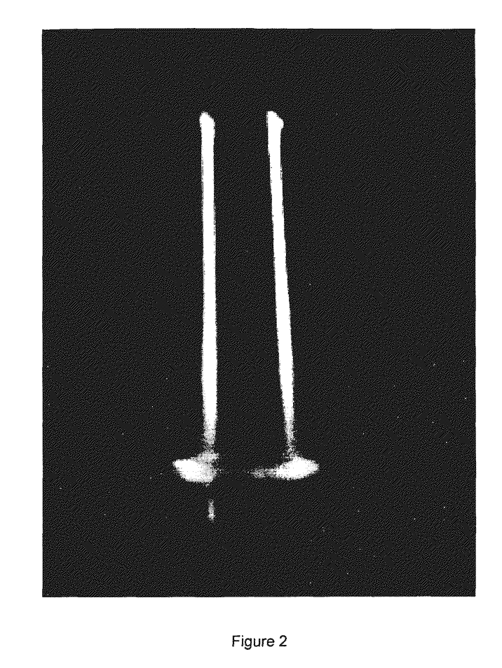

FIG. 2 is a photograph of the plasma jets observed when operating the apparatus of FIG. 1 with laminar gas flow;

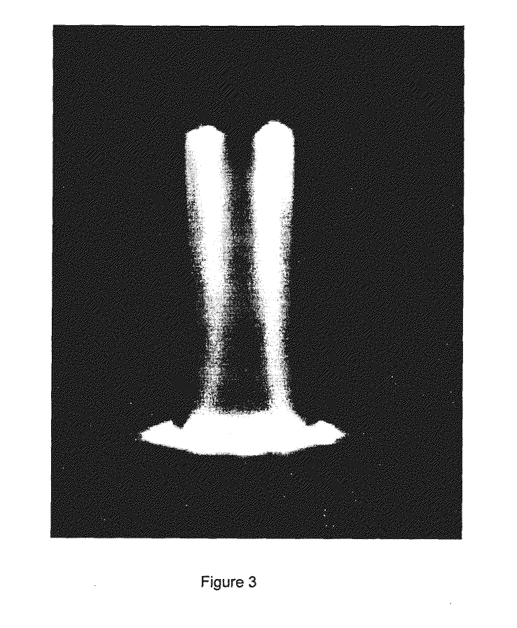

FIG. 3 is a photograph of the plasma jets observed when operating the apparatus of FIG. 1 with turbulent gas flow;

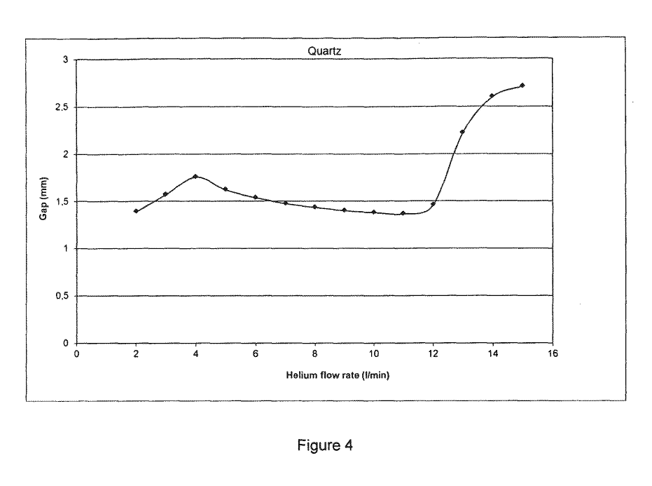

FIG. 4 is a graph showing the limits of the laminar and turbulent flow regimes in the apparatus of FIG. 1 in terms of outlet gap and helium processing gas flow rate;

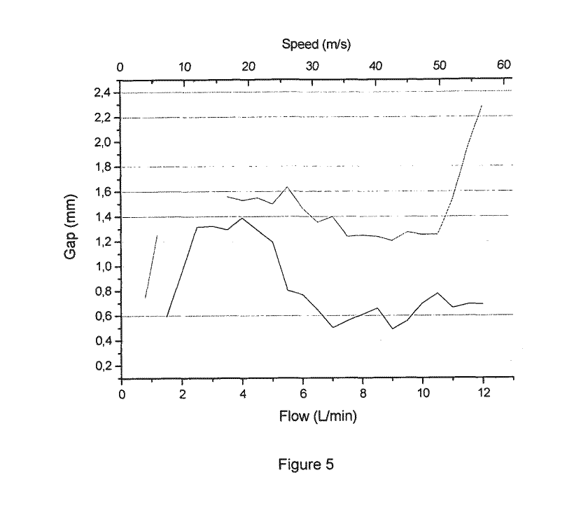

FIG. 5 is a graph showing the limits of the laminar and turbulent flow regimes in the apparatus of FIG. 1 when the outlet gap of the plasma tube is narrowed or widened;

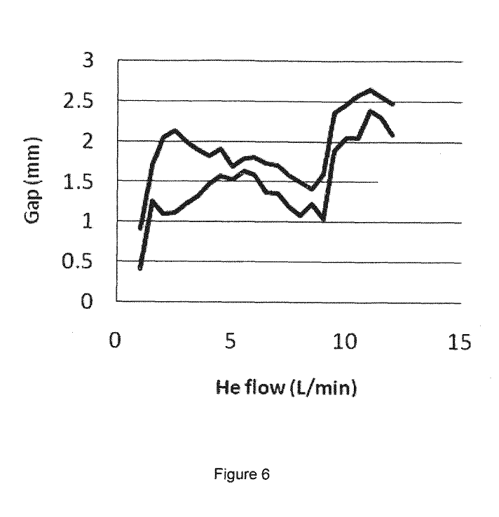

FIG. 6 is a graph showing the limits of the laminar and turbulent flow regimes in apparatus of FIG. 1 having different plasma tube lengths.

The apparatus of FIG. 1 comprises two electrodes (11, 12) positioned within a plasma tube (13) defined by a dielectric housing (14) and having an outlet (15). The electrodes (11, 12) are needle electrodes both having the same polarity and are connected to a suitable radio frequency (RF) power supply. The electrodes (11, 12) are each positioned within a narrow channel (16 and 17 respectively), for example 0.1 to 5 mm wider than the electrode, preferably 0.2 to 2 mm wider than the electrode, communicating with plasma tube (13). The process gas is fed to a chamber (19) whose outlets are the channels (16, 17) surrounding the electrodes. The chamber (19) is made of a heat resistant, electrically insulating material which is fixed in an opening in the base of a metal box. The metal box is grounded but grounding of this box is optional. The chamber (19) can alternatively be made of an electrically conductive material, provided that all the electrical connections are isolated and any part in potential contact with the plasma is covered by a dielectric. The channels (16, 17) thus form the inlet to dielectric housing (14) for process gas. An atomizer (21) having an inlet (22) for surface treatment agent is situated adjacent to the electrode channels (16, 17) and has atomizing means (not shown) and an outlet (23) feeding atomized surface treatment agent to the plasma tube (13). The chamber (19) holds the nebuliser (21) and needle electrodes (11, 12) in place. The dielectric housing (14) can be made of any dielectric material. Experiments described below were carried out using quartz dielectric housing (14) but other dielectrics, for example glass or ceramic or a plastic material such as polyamide, polypropylene or polytetrafluoroethylene, for example that sold under the trade mark ‘Teflon’, can be used. The dielectric housing (14) can be formed of a composite material, for example a fiber reinforced plastic designed for high temperature resistance.

The substrate (25) to be treated is positioned at the plasma tube outlet (15). The substrate (25) is laid on a dielectric support (27). The substrate (25) is arranged to be movable relative to the plasma tube outlet (15). The dielectric support (27) can for example be a dielectric layer (27) covering a metal supporting plate (28). The metal plate (28) as shown is grounded but grounding of this plate is optional. If the metal plate (28) is not grounded, this may contribute to the reduction of arcing onto a conductive substrate, for example a silicon wafer. The gap (30) between the outlet end of the dielectric housing (14) and the substrate (25) is the only outlet for the process gas fed to the plasma tube (13).

The electrodes (11, 12) are sharp surfaced and are preferably needle electrodes. The use of a metal electrode with a sharp point facilitates plasma formation. As an electric potential is applied to the electrode, an electric field is generated which accelerates charged particles in the gas forming a plasma. The sharp point aids the process, as the electric field density is inversely proportional to the radius of curvature of the electrode. Needle electrodes thus possess the benefit of creating a gas breakdown using a lower voltage source because of the enhanced electric field at the sharp extremity of the needles.

When power is applied, local electric fields form around the electrode. These interact with the gas surrounding the electrode and a plasma is formed. The plasma generating apparatus can thus operate without special provision of a counter electrode. Alternatively a grounded counter electrode may be positioned at any location along the axis of the plasma tube.

The power supply to the electrode or electrodes is a radio frequency power supply as known for plasma generation, that is in the range 1 kHz to 300 GHz. Our most preferred range is the very low frequency (VLF) 3 kHz-30 kHz band, although the low frequency (LF) 30 kHz-300 kHz range can also be used successfully. One suitable power supply is the Haiden Laboratories Inc. PHF-2K unit which is a bipolar pulse wave, high frequency and high voltage generator. It has a faster rise and fall time (<3 μs) than conventional sine wave high frequency power supplies. Therefore, it offers better ion generation and greater process efficiency. The frequency of the unit is also variable (1-100 kHz) to match the plasma system. An alternative suitable power supply is an electronic ozone transformer such as that sold under the reference ETI110101 by the company Plasma Technics Inc. It works at fixed frequency and delivers a maximum power of 100 Watt.

The surface treatment agent which is fed to the atomizer (21) can for example be a polymerisable precursor. When a polymerisable precursor is introduced into the plasma a controlled plasma polymerisation reaction occurs which results in the deposition of a polymer on any substrate which is placed adjacent to the plasma outlet. Using the process of the invention, a range of functional coatings have been deposited onto numerous substrates. These coatings are grafted to the substrate and retain the functional chemistry of the precursor molecule.

The atomizer (21) preferably uses a gas to atomize the surface treatment agent. For example the process gas used for generating the plasma is used as the atomizing gas to atomize the surface treatment agent. The atomizer (21) can for example be a pneumatic nebuliser, particularly a parallel path nebuliser such as that sold by Burgener Research Inc. of Mississauga, Ontario, Canada, under the trade mark Ari Mist HP, or that described in U.S. Pat. No. 6,634,572. The atomizer can alternatively be an ultrasonic atomizer in which a pump is used to transport the liquid surface treatment agent into an ultrasonic nozzle and subsequently it forms a liquid film onto an atomizing surface. Ultrasonic sound waves cause standing waves to be formed in the liquid film, which result in droplets being formed. The atomizer preferably produces drop sizes of from 10 to 100 μm, more preferably from 10 to 50 μm. Suitable atomizers for use in the present invention include ultrasonic nozzles from Sono-Tek Corporation, Milton, N.Y., USA. Alternative atomizers may include for example electrospray techniques, methods of generating a very fine liquid aerosol through electrostatic charging. The most common electrospray apparatus employs a sharply pointed hollow metal tube, with liquid pumped through the tube. A high-voltage power supply is connected to the outlet of the tube. When the power supply is turned on and adjusted for the proper voltage, the liquid being pumped through the tube transforms into a fine continuous mist of droplets. Inkjet technology can also be used to generate liquid droplets without the need of a carrier gas, using thermal, piezoelectric, electrostatic and acoustic methods.

While it is preferred that the atomizer (21) is mounted within the housing (14), an external atomizer can be used. This can for example feed an inlet tube having an outlet in similar position to outlet (23) of nebuliser (21). Alternatively the surface treatment agent, for example in a gaseous state, can be incorporated in the flow of process gas entering chamber (19). In a further alternative the electrode can be combined with the atomizer in such a way that the atomizer acts as the electrode. For example, if a parallel path atomizer is made of conductive material, the entire atomizer device can be used as an electrode. Alternatively a conductive component such as a needle can be incorporated into a non-conductive atomizer to form the combined electrode-atomizer system.

The process gas entering chamber (19) is constrained to flow through the two narrow channels (16, 17) past the electrodes (11, 12). Preferably the process gas comprises an inert gas substantially consisting of helium and/or argon, that is to say comprising at least 90% by volume, preferably at least 95%, of one of these gases or a mixture of both of them, optionally with up to 5 or 10% of another gas, for example nitrogen or oxygen. A higher proportion of an active gas such as oxygen can be used if it is required to react with the surface treatment agent. When the electrodes (11, 12) are connected to a low RF oscillating source, a plasma is formed in the flow of process gas from each of the channels (16 and 17). The two plasma jets created by the channels (16, 17) enter the plasma tube (13) and generally extend to the outlet (15) of the plasma tube.

The plasma jets can stay directional in laminar flow regime, as shown in FIG. 2, unless steps are taken to change the gas flow regime. FIG. 2 is a photograph of the two plasma jets observed when operating the apparatus of FIG. 1 with a helium process gas flow of 5 litres per minute and a wide outlet of the plasma tube (13). We have found that plasma jets formed using helium as process gas are especially liable to stay in laminar flow regime. This laminar flow regime may present some disadvantages when applying a surface treatment agent to a substrate. The directional jets may lead to patterning of the deposition. Furthermore, the jets are made of gas of very high velocity going up to several tens of metres/second and these jets can interact with each other and with the tube walls, leading to the creation of a vortex in which the atomized surface treatment agent can be trapped. If the atomized surface treatment agent is a precursor of a polymer to be formed on the substrate surface, having sprayed precursor trapped in the vortex largely increases the precursor residence time in the hot zone of the plasma, which is a factor favoring the polymerization in the gas phase, leading to the deposition of a powdery low density film. Also, streamers may develop between the needle electrodes (11, 12) and the substrate (25) or grounded electrode if used. Streamers are also responsible for powder formation in the plasma by premature reaction of the surface treatment agent because of the high energy concentration in the streamer. When depositing on a conductive substrate such as a conductive wafer, streamers are even more difficult to avoid because of the charge spreading at the surface of the conductor.

One way to prevent streamers developing between the powered electrodes (11, 12) and the substrate (25) is to add nitrogen to the processing gas to quench the plasma as described in WO2009/034012, but this solution is detrimental to the energy applied to the atomized surface treatment agent, for example the energy available for precursor dissociation when depositing a polymer of a precursor from the plasma. As a result, addition of nitrogen to the processing gas can lead to the deposition of soft, poorly polymerized films. Another way to prevent streamer formation is to decrease the electric field by increasing the distance between the electrodes (11, 12) and the grounded plate (28) covered by dielectric (27). This also decreases the energy available for precursor dissociation and polymer deposition.

According to the present invention powder formation in the plasma is inhibited by creating a turbulent gas flow regime within the plasma tube (13). For a given process gas, the gas flow can be varied between laminar and turbulent flow by varying the gap (30) at the outlet of plasma tube (13), that is the gap between the dielectric housing (14) and the substrate (25), and the flow of the processing gas entering the tube (13) through channels (16,17). The process and apparatus of the invention is especially advantageous in promoting a turbulent gas flow regime when using helium as process gas because plasma jets formed using helium are more likely to remain in laminar flow. When a heavier gas such as argon having a smaller kinematic viscosity than helium (kinematic viscosity is the ratio between fluid dynamic viscosity and fluid density) is used as process gas, the gas flow is more likely to become turbulent in the plasma tube because the corresponding Reynolds number is larger. However the process and apparatus of the invention can also be used with such heavier gases to ensure that turbulent flow is achieved.

The plasma jets in turbulent regime appear as shown in FIG. 3. FIG. 3 is a photograph of the plasma jets observed when operating the apparatus of FIG. 1, having two needle electrodes (11, 12) surrounded by dielectric creating 2 mm diameter channels (16, 17) surrounding the needles, with a helium process gas flow of 10 litres per minute and a gap (30) of 1 mm between the dielectric housing (14) and a substrate (25). The dielectric housing (14) defined a plasma tube (13) of diameter 18 mm and length 75 mm from the electrodes (11, 12) to the outlet (15).

We have carried out experiments using helium as process gas in the apparatus of FIG. 1 at various flow rates with various widths of gap (30) and observing whether the plasma jet formed showed a laminar (as FIG. 2) or turbulent (as FIG. 3) regime. For each flow rate, the gap (30) was incrementally increased. The results, when using the Plasma Technics ETI110101 unit at 20 kHz and maximum power of 100 watts, are shown graphically in FIG. 4. FIG. 4 is a graph of maximum outlet gap (30) (left hand scale) to achieve a FIG. 3 type plasma discharge at a given helium flow (bottom scale). At a flow rate of 2.1 litres/minute the gas speed at the outlet was 10 m/s and the Reynolds number was 27. At a flow rate of 6.3 l/m the gas speed at the outlet was 30 m/s and the Reynolds number was 467. A laminar flow regime occurs for all the gap/processing gas conditions above the line shown in FIG. 4, this line being the border between the two regimes. For most gap/processing gas conditions above the line shown in FIG. 4, two separated plasma jets are clearly visible as depicted in FIG. 2. For some gap/processing gas conditions which are only just above the line shown in FIG. 4, there may be a transitory regime in which two unstable plasma jets are seen. For gap/processing gas conditions below the line, the regime is turbulent and presents an intense, white light emission as shown in FIG. 3. The change in color of the discharge is associated with a change in gas composition in the dielectric tube because less N2 or O2 can diffuse into the plasma tube. Reason is the large gas velocity at tube outlet when combining a large flow and a small gap.

We have found that when depositing a polymer of a precursor onto a glass substrate from a plasma having a turbulent regime, non-powdery, dense films are deposited. Formation of a vortex in the plasma tube is avoided due to the spatial homogenization provided by the turbulent regime. When depositing on conductive silicon wafer, no streamers were detected even when working at full energy of the source power and without any addition of nitrogen.

It will be seen from FIG. 4 that for a wide range of flow rates a turbulent regime is achieved with a gap (30) of less than 1.5 mm. This applies for helium flow rates in the range 1 to 12 litres/minute. The invention thus includes a process for plasma treating a substrate by applying a radio frequency high voltage to at least one electrode positioned within a dielectric housing having an inlet and an outlet while causing helium process gas to flow from the inlet past the electrode to the outlet, thereby generating a non-equilibrium atmospheric pressure plasma, incorporating an atomized surface treatment agent in the non-equilibrium atmospheric pressure plasma, and positioning the substrate adjacent to the plasma outlet so that the surface is in contact with the plasma and is moved relative to the plasma outlet, characterised in that the gap between the plasma outlet and the substrate is controlled to be less than 1.5 mm. The gap (30) is preferably less than 1.5 mm., more preferably below 1 mm., and most preferably below 0.75 mm., for example 0.25 to 0.75 mm. A turbulent regime can be achieved according to the invention using a larger gap, for example up to 3 mm, with a higher helium flow rate, for example 14 litres/minute, but a smaller gap allows achievement of a turbulent regime at lower Helium flow and so more economically viable conditions

According to a preferred aspect of the invention the surface area of the gap (30) is less than 35 times the area of the inlet or inlets for process gas. In the apparatus of FIG. 1 the surface area of the gap (30) is preferably less than 25, more preferably less than 20, times the sum of the areas of the channels (16 and 17). More preferably the surface area of the gap (30) is less than 10 times the area of the inlet or inlets for process gas, for example 2 to 10 times the area of the inlet or inlets for process gas. In the apparatus of FIG. 1 having two 1 mm diameter needle electrodes (11, 12) surrounded by 2 mm diameter channels (16, 17) the area of each channel free for gas flow around the needle is thus 2.35 mm² (total 4.7 mm²). If the gap (30) between dielectric housing (14) and substrate (25) is 1.5 mm, the area of the gap (30) is 70 mm², so that the surface area of the gap (30) is about 15 times the sum of the areas of the inlets for process gas. If the gap (30) is 1 mm, the surface area of the gap (30) is about 10 times the sum of the areas of the inlets for process gas, and if the gap (30) is 0.75 mm surface area of the gap (30) is about 7.5 times the sum of the areas of the inlets for process gas.

Numerous plasma jets are studied today. Most of them are flowing in air and impacting a surface. The peculiarity of the preferred configuration of the present invention is that two impacting jets are confined in a single tube of 2 cm in diameter. This tube is made of quartz, a transparent and insulating material. It helps in limiting the jet interaction with air previous to the surface impact and participates to the discharge development. Needles are used to initiate a plasma in each helium jet. The excitation frequency is in the range of 20 kHz. The discharge development is characterized by short exposure time pictures, emission spectroscopy and voltage current measurement.

As shown by FIGS. 2 and 3, the appearance of the discharge is largely modified by the gas flow dynamic. The transition from one regime to the other occurs, for example, by changing the gas flow or the distance between the bottom of the confinement and the surface.

According to flow dynamic modeling with ‘FLUENT’ software the transition of the discharge from one regime to the other one is correlated to a transition from a laminar flow to a turbulent one. This transition is also associated to a modification of the air intake by the bottom of the confinement tube. The detailed study of the discharge development shows that in the two regimes, each breakdown start at the needles, but in the turbulent regime, it is a more homogeneous, glow-like discharge. In the laminar regime, we observe a “plasma bullet” phenomenon just before the positive breakdown, that does not occur, nor during negative breakdown nor in turbulent mode.

We have found that for a given helium flow rate, the width of gap (30) at which the plasma discharge changes between a pair of plasma jets as shown in FIG. 2 and a more uniform discharge as shown in FIG. 3 varies depending on whether the gap is being widened or narrowed. The experiment of FIG. 4 was repeated with a complementary experiment in which for each helium flow rate, the gap (30) was incrementally decreased. The results are shown in FIG. 5, which is a graph of maximum outlet gap (30) (left hand scale) to achieve a FIG. 3 type discharge at a given helium flow (bottom scale) or velocity (top scale). The upper line shows the results when increasing the gap (30) at a given flow rate, so that the discharge is changing from a FIG. 3 type discharge to a FIG. 2 type discharge. This result is close to the result shown in FIG. 4. The lower line shows the results when decreasing the gap (30) at a given flow rate, so that the discharge is changing from a FIG. 2 type discharge to a FIG. 3 type discharge. It will be seen that FIG. 5 shows a kind of hysteresis for switching between the two types of discharge. Transition from a FIG. 3 type discharge to a FIG. 2 type discharge appears for a larger gap (30) width than transition from a FIG. 2 type discharge to a FIG. 3 type discharge.

The experiment of FIG. 4 was repeated comparing a dielectric housing (14) defining a plasma tube (13) of diameter 18 mm and length 75 mm from the electrodes (11, 12) to the outlet (15) with a dielectric housing defining a plasma tube of diameter 16 mm and length 55 mm. The results are shown in FIG. 6, which is a graph of maximum outlet gap (30) (left hand scale) to achieve a FIG. 3 type plasma discharge at a given helium flow (bottom scale). The upper line shows results for a 75 mm plasma tube (13), which are similar to those of FIG. 4. The lower line shows results for a 55 mm plasma tube. It can be seen that for a shorter plasma tube, a FIG. 3 type plasma discharge is more difficult to obtain, that is the outlet gap (30) needs to be smaller for a given helium flow rate, although the difference between the results for the 75 mm plasma tube and the results for the 55 mm plasma tube is not large. If the tube length is increased beyond 75 mm, it may be easier to achieve a uniform discharge even when the surface area of the gap (30) is less than 35 times the area of the inlet or inlets for process gas.

We have also found that a FIG. 3 type plasma discharge is easier to obtain, that is the outlet gap (30) does not need to be so small for a given helium flow rate, when a thinner plasma tube (13) is used, for example a dielectric housing (14) defining a 8 mm diameter plasma tube instead of a 18 mm plasma tube. If the tube diameter is less than 18 mm, it may be easier to achieve a uniform discharge even when the surface area of the gap (30) is less than 35 times the area of the inlet or inlets for process gas.

The surface treatment agent used in the present invention is a precursor material which is reactive within the non-equilibrium atmospheric pressure plasma or as part of a plasma enhanced chemical vapour deposition (PE-CVD) process and can be used to make any appropriate coating, including, for example, a material which can be used to grow a film or to chemically modify an existing surface. The present invention may be used to form many different types of coatings. The type of coating which is formed on a substrate is determined by the coating-forming material(s) used, and the process of the invention may be used to (co)polymerise coating-forming monomer material(s) onto a substrate surface.

The coating-forming material may be organic or inorganic, solid, liquid or gaseous, or mixtures thereof. Suitable organic coating-forming materials include carboxylates, methacrylates, acrylates, styrenes, methacrylonitriles, alkenes and dienes, for example methyl methacrylate, ethyl methacrylate, propyl methacrylate, butyl methacrylate, and other alkyl methacrylates, and the corresponding acrylates, including organofunctional methacrylates and acrylates, including poly(ethyleneglycol) acrylates and methacrylates, glycidyl methacrylate, trimethoxysilyl propyl methacrylate, allyl methacrylate, hydroxyethyl methacrylate, hydroxypropyl methacrylate, dialkylaminoalkyl methacrylates, and fluoroalkyl (meth)acrylates, for example heptadecylfluorodecyl acrylate (HDFDA) of the formula

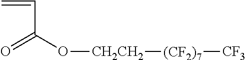

methacrylic acid, acrylic acid, fumaric acid and esters, itaconic acid (and esters), maleic anhydride, styrene, α-methylstyrene, halogenated alkenes, for example, vinyl halides, such as vinyl chlorides and vinyl fluorides, and fluorinated alkenes, for example perfluoroalkenes, acrylonitrile, methacrylonitrile, ethylene, propylene, allyl amine, vinylidene halides, butadienes, acrylamide, such as N-isopropylacrylamide, methacrylamide, epoxy compounds, for example glycidoxypropyltrimethoxysilane, glycidol, styrene oxide, butadiene monoxide, ethyleneglycol diglycidylether, glycidyl methacrylate, bisphenol A diglycidylether (and its oligomers), vinylcyclohexene oxide, conducting polymers such as pyrrole and thiophene and their derivatives, and phosphorus-containing compounds, for example dimethylallylphosphonate. The coating forming material may also comprise acryl-functional organosiloxanes and/or silanes.

Suitable inorganic coating-forming materials include metals and metal oxides, including colloidal metals. Organometallic compounds may also be suitable coating-forming materials, including metal alkoxides such as titanates, tin alkoxides, zirconates and alkoxides of germanium and erbium. We have found that the present invention has particular utility in providing substrates with siloxane-based coatings using coating-forming compositions comprising silicon-containing materials. Suitable silicon-containing materials for use in the method of the present invention include silanes (for example, silane, alkylsilanes, alkylhalosilanes, alkoxysilanes), silazanes, polysilazanes and linear (for example, polydimethylsiloxane or polyhydrogenmethylsiloxane) and cyclic siloxanes (for example, octamethylcyclotetrasiloxane or tetramethylcyclotetrasiloxane), including organo-functional linear and cyclic siloxanes (for example, Si—H containing, halo-functional, and haloalkyl-functional linear and cyclic siloxanes, e.g. tetramethylcyclotetrasiloxane and tri(nonofluorobutyl)trimethylcyclotrisiloxane). A mixture of different silicon-containing materials may be used, for example to tailor the physical properties of the substrate coating for a specified need (e.g. thermal properties, optical properties, such as refractive index, and viscoelastic properties). Particularly preferred silicon-containing precursors for depositing polymerised SiCO films are tetraethyl orthosilicate Si(OC₂H₅)₄ and tetramethylcyclotetrasiloxane (CH₃(H)SiO)₄.

Tetraethyl orthosilicate is also suitable for depositing SiO₂ layers provided that oxygen is present in the process gas. In previous plasma jet processes, deposition of SiO₂ layers was possible without oxygen in the process gas because of retro-diffusion of oxygen into the plasma tube. In the present invention, because of the high processing gas velocity at the exit of the tube resulting from a low gap and large helium flow rate, conditions are unfavorable for the retro-diffusion of oxygen inside the plasma tube. However deposition of SiO₂ layers can easily be achieved via the addition of O₂ to the processing gas, for example 0.05 to 20% by volume O₂, particularly 0.5 to 10% O₂. We have found that transition to SiO₂ occurs in turbulent regime using a mixture of O₂/He.

The process of the invention is particularly suitable for coating electronic equipment including textile and fabric based electronics printed circuit boards, displays including flexible displays, and electronic components such as semiconductor wafers, resistors, diodes, capacitors, transistors, light emitting diodes (leds), organic leds, laser diodes, integrated circuits (ic), ic die, ic chips, memory devices logic devices, connectors, keyboards, semiconductor substrates, solar cells and fuel cells. Optical components such as lenses, contact lenses and other optical substrates may similarly be treated. Other applications include military, aerospace or transport equipment, for example gaskets, seals, profiles, hoses, electronic and diagnostic components, household articles including kitchen, bathroom and cookware, office furniture and laboratory ware.

The invention is illustrated by the following Examples

### EXAMPLES 1 TO 3

The apparatus of FIG. 1 was used to deposit SiCO film on a conductive silicon wafer substrate. The electrodes (11, 12) were connected to the Plasma Technics ETI110101 unit operated at 20 kHz and maximum power of 100 watts. Helium process gas was flowed through the apparatus at 8 litres/minute. The two 1 mm diameter needle electrodes (11, 12) are surrounded by dielectric creating 2 mm diameter channels (16, 17) surrounding the needles forcing the gas to acquire a certain velocity and forming a jet. Tetraethyl orthosilicate precursor was supplied to the atomizer (21), which was the Ari Mist HP supplied by Burgener Inc. The dielectric housing (14) defined a plasma tube (13) of diameter 18 mm and length 75 mm from the electrodes (11, 12) to the outlet (15). The gap (30) between quartz housing (14) and the silicon wafer substrate was 0.8 mm. The surface area of the gap (30) was about 10 times the sum of the areas of the inlets (16, 17) for process gas.

In Example 1, a grounded counter electrode was positioned externally to the plasma tube (13) at the very top of the tube housing (14), close to the powered needle electrodes (11,12).

In Example 2, no counter electrode was used.

In Example 3, a grounded counter electrode was positioned externally to the plasma tube (13) 14 mm from the bottom of the dielectric housing (14).

A turbulent regime was created in the plasma tube (13) and an intense, white light emission as shown in FIG. 3 was observed in each of Examples 1 to 3.

The level of light reflection from the film deposited, compared to light scattering, was measured for the films from each of the Examples using a spectroscopic Ellipsometer UVSEL produced by jobin yvon. A beam of light of wavelength 450 nm (in the middle of the visible spectrum) was directed to the surface of the film, at an angle of 70.4°. A photoelectric light detector is positioned just opposite so that if there is a specular reflection, light is collected by the detector. The smoother and more reflective is the film, the higher is the voltage recorded by the light detector; this voltage is proportional to the light collected by the detector. We measured first a surface polished silicon wafer and recorded a voltage of 130 mV. This voltage corresponds to the case of light collected after reflection on a perfectly flat highly reflective surface. The voltages recorded for the films from each of the Examples are listed in Table 1.

Comparative examples C1 to C3 were carried out using the conditions of Examples 1 to 3 respectively except that the gap (30) between quartz housing (14) and the silicon wafer substrate was 3 mm. In each of comparative examples C1 to C3 a laminar regime was created in the plasma tube (13) and two separated plasma jets were clearly visible.

TABLE 1

| | Voltage at light |
|---|---|
| Example | detector (mV) |
| C1 | 15 |
| 1 | 135 |
| C2 | 70 |
| 2 | 145 |
| C3 | 45 |
| 3 | 105 |

The high voltage recorded for Examples 1 to 3 means a high level of film reflectivity and a low level of scattering, indicative of a smooth, low porosity film. As can be seen, Examples 1 to 3 using a small gap (30) to create a turbulent regime in the plasma tube (13) formed smoother and less porous films than the comparative examples. The low voltage recorded in Comparative Example C1 indicates a rough film from which the light is not reflected to the detector but is scattered in all directions.

1. A process for plasma treating a substrate by applying a radio frequency high voltage to at least one electrode positioned within a dielectric housing having an inlet and an outlet while causing a process gas to flow from the inlet past the electrode to the outlet, thereby generating a non-equilibrium atmospheric pressure plasma, incorporating an atomized or gaseous surface treatment agent in the non-equilibrium atmospheric pressure plasma, and positioning the substrate adjacent to the outlet of the dielectric housing so that the surface of the substrate is in contact with the plasma and is moved relative to the outlet of the dielectric housing, wherein the flow of process gas and the gap between the outlet of the dielectric housing and the substrate are controlled so that the process gas has a turbulent flow regime within the dielectric housing.

2. A process according to claim 1, wherein the gap between the outlet of the dielectric housing and the substrate is controlled to be less than 1.5 mm.

3. A process according to claim 2, wherein the flow of process gas is monitored and the gap between the plasma outlet and the substrate is controlled to be below the line shown in FIG. 4 of the accompanying drawings.

4. A process according to claim 1, wherein the surface area of the gap between the outlet of the dielectric housing and the substrate is less than 35 times the area of the inlet for process gas.

5. A process according to claim 4, wherein the surface area of the gap between the outlet of the dielectric housing and the substrate is from 2 to 10 times the area of the inlet for process gas.

6. A process according to claim 1, wherein the at least one electrode is a needle electrode.

7. A process according to claim 6, wherein the at least one electrode is surrounded by a narrow channel through which the process gas flows.

8. A process according to claim 1, wherein the substrate is positioned on a dielectric layer covering a metallic plate and no counter electrode is used.

9. A process according to claim 1, wherein a grounded counter electrode is positioned externally to the plasma tube and is located at a position along the plasma tube.

10. A process according to claim 1, wherein the process gas carries the surface treatment agent past the electrode.

11. A process according to claim 1, wherein the electrode is combined with an atomizer for the surface treatment agent within the housing.

12. A process according to claim 11, wherein the radio frequency high voltage is applied to at least two electrodes positioned within the dielectric housing surrounding the atomizer and having the same polarity.

13. A process according to claim 11, wherein the electrode is a tubular electrode surrounding the atomizer.

14. An apparatus for plasma treating a substrate, comprising:
a radio frequency high voltage source connected to at least one electrode positioned within a dielectric housing having an inlet for process gas and an outlet arranged so that process gas flows from the inlet past the electrode to the outlet;
means for introducing an atomized surface treatment agent in the dielectric housing;
support means for the substrate adjacent to the outlet of the dielectric housing; and
wherein the support means are positioned so that the surface area of the gap between the outlet of the dielectric housing and the substrate is less than 35 times the area of the inlet for process gas.
